(19) United States
(12) Patent Application Publication
(10) Pub. No.: US 2010/0055813 A1
(43) Pub. Date: Mar. 4, 2010

(54) Method of Packaging Light Emitting Diode on Through-Hole Substrate

(76) Inventors: Ching-cherng SUN, Jhongli City (TW); Tsung-Xian Lee, Jhongli City (TW)

Correspondence Address: HDLS Patent & Trademark Services, P.O. BOX 220746, CHANTILLY, VA, 20153-0746, US

(21) Appl. No.: 12/206,710

(22) Filed: Sep. 8, 2008

(30) Foreign Application Priority Data
Aug. 27, 2008 (TW) 097132633

(51) Int. Cl. H01L 33/00

(52) U.S. Cl. 438/27; 257/E33.067; 257/E33.061

(57) ABSTRACT

In a method of packaging a light emitting diode on a through-hole substrate, through holes are created and a wire bonded light emitting diode (LED) chip is set on the substrate, and a lens is set on the through holes and the wire bonded LED chip. The through holes are provided for filling a phosphor into the lens and extracting air in the lens, so that the phosphor can be coated uniformly on the wire bonded LED chip. After the phosphor is solidified, the packaging of the LED is completed. The method can produce a desired shape of the phosphor while the cost is being taken into consideration, and thus the invention can help manufacturers to produce an accurate shape of the phosphor to provide an LED light source of a better quality without involving a complicated procedure.

### BACKGROUND OF THE INVENTION

1. Field of Invention

The present invention relates to a method of packaging a light emitting diode on a through-hole substrate, and more particularly to a method of accurately forming a phosphor in a light emitting diode while taking the cost into consideration, and effectively overcoming the difficulty of controlling the shape of the phosphor in a conventional light emitting diode and the problems caused by a poor quality of the conventional light emitting diode.

2. Description of Related Art

In recent years, the manufacturing cost of light emitting diode (LED) becomes increasingly lower and both efficiency and brightness of the LED become increasing higher. With the advantages of long life, high safety, excellent light emission rate (low power), rich colors, outstanding driving and controlling flexibility, small volume and good environmental protection, the light emitting diode becomes popular in the general illumination market and its demand grows rapidly.

The structure of a white light LED that gradually substitutes traditional light sources comprises an LED chip installed at the bottom of the LED, a phosphor coated onto the LED chip, and a lens insulated from the outside. The LED chip is made of a material (such as a semiconductor) with a lower band gap, and thus a monochromatic light (such as a blue light) with a short wavelength will be emitted after the electric energy is excited, and the monochromatic light with the short wavelength can be absorbed by the phosphor and excited to emit a monochromatic light (such as a yellow light) with a long wavelength, and these monochromatic lights are mixed to produce a white light.

In the foregoing structure, the properties (light extraction efficiency, color temperature and color uniformity, etc) of the white light LED, particularly the phosphor, are affected, and the phosphor is coated onto the LED chip mostly by a titration method, and thus the shape of the phosphor cannot be controlled easily or accurately. Therefore, the inventor of the present invention disclosed the method of packing LED in accordance with the invention to overcome the shortcomings of the prior art and provide a white light LED with a better quality while taking the manufacturing cost into consideration to avoid creating a burden to related manufacturers of the industry.

### SUMMARY OF THE INVENTION

In view of the foregoing shortcomings of the prior art that cannot control the parameters of a phosphor easily during the packaging process of a light emitting diode, and causes a poor quality of the light emitting diode, the inventor of the present invention based on years of experience in the related industry to conduct extensive researches and experiments, and finally invented a method of packaging a light emitting diode on a through-hole substrate to overcome the shortcomings of the prior art.

Therefore, it is a primary objective of the present invention to provide a method of packaging a light emitting diode on a through-hole substrate, wherein a plurality of through holes are created on a substrate in advance, and a wire bonded LED chip and a lens having at least one phosphor containing groove are combined sequentially on the substrate, so that a phosphor can be filled into the phosphor containing groove from the through holes and air can be extracted from the phosphor containing groove to coat the phosphor onto the LED chip. Finally, the phosphor is solidified to complete packaging the light emitting diode. The method of the invention not only accurately controls the parameters of the phosphor, but also takes the cost into consideration. The invention can assist manufacturers to form an accurate shape of the phosphor to obtain an LED light source with a better quality without involving a complicated procedure. This technology can be applied to related industries, particularly the packaging and illumination industries.

### BRIEF DESCRIPTION OF THE DRAWINGS

FIG. 1 is a flow chart of the present invention; and

FIG. 2 is a schematic view of a structure of the present invention.

### DETAILED DESCRIPTION OF THE INVENTION

To make it easier for our examiner to understand the technical characteristics of the invention, we use preferred embodiments together with the attached drawings for the detailed description of the invention.

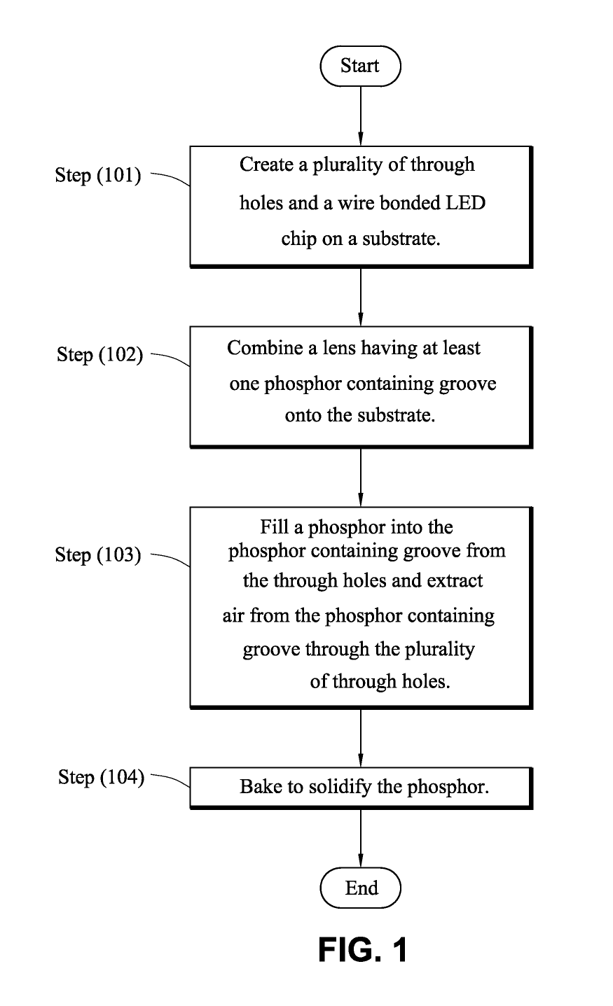

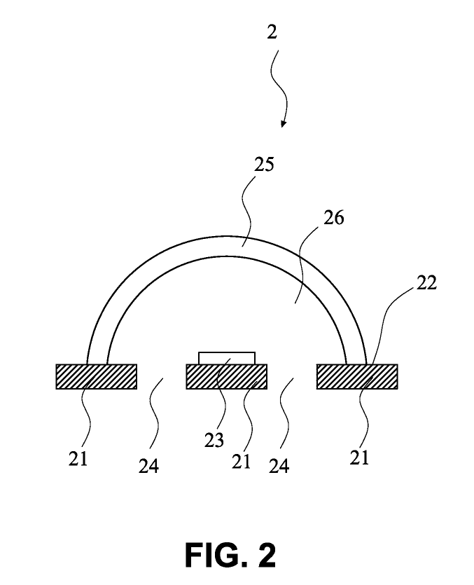

The present invention discloses a method of packaging a light emitting diode on a through-hole substrate, wherein the phosphor determines the quality of a white light LED, and thus the parameters including the position, shape, size, concentration, uniformity and thickness of the phosphor are important factors in the manufacturing process of the white light LED. Based on the foregoing parameters, additional steps are added to the manufacturing process of the light emitting diode to accurately control the parameters of the phosphor, but the procedure is too complicated and incurs a higher cost. In view of the shortcomings of the prior art, the present invention provides a method of packaging a light emitting diode. The method not only accurately controls the parameters of the phosphor, but also takes the cost in to consideration. With reference to FIGS. 1 and 2, the method of the invention comprises the steps of:

Step (101): providing a substrate 21, wherein a plurality of through holes 24 and a wire bonded LED chip 23 are created on the substrate 21;

Step (102): providing a lens 25 (made of a transparent optical material), wherein the lens 25 has at least one phosphor containing groove 26 (whose size and shape can be changed according to actual needs, and the shape is in a horizontal, wavy, arc or irregular shape, etc) combined onto the substrate 21, for containing the wire bonded LED chip 23 and the through holes 24;

Step (103): providing an appropriate quantity (such as a multilayer, an uneven thickness or an unequal thickness) of phosphor (including a fluorescent powder and a glue) to be filled into the phosphor containing groove 26 from the through holes 24 and extracting air from the phosphor containing groove 26;

Step (104): baking to solidify the phosphor and complete the packaging of a light emitting diode 2.

With reference to FIG. 2 for a side sectional view of a light emitting diode 2 produced by the packaging method of the present invention, the light emitting diode 2 is built on a surface 22 of the substrate 21, and the surface 22 includes the wire bonded LED chip 23 and the through holes 24, and the phosphor containing groove 26 contained in the lens 25 combined onto the surface 22 of the substrate 21 contains the wire bonded LED chip 23, the through holes 24 and the phosphor.

Therefore, the method of the invention has the following advantages:

1. Since the through holes 24 are created on the substrate 21 in advance and the phosphor is filled into the phosphor containing groove 26 through the through holes 24, this manufacturing process controls different parameters particularly the shape of the phosphor, such that the phosphor can be coated uniformly onto the LED chip 23 to produce a light source of a light emitting diode 2 with high efficiency and high color uniformity.

2. Since the through holes 24 are provided for filling the phosphor into the phosphor containing groove 26 and extracting air in the phosphor containing groove 26, no bubbles will be produced in the phosphor containing groove 26, and no precipitate will be formed, and thus the uniform concentration of the phosphor will not be affected.

While the invention has been described by examples and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of packaging a light emitting diode on a through-hole substrate, comprising the steps of:
providing a substrate, and the substrate comprising a plurality of through holes and a wire bonded LED chip;
providing a lens having at least one phosphor containing groove, for combining the lens onto the substrate, and containing the wire bonded LED chip and the through holes;
filling an appropriate amount of phosphor into the phosphor containing groove from the through holes, and extracting air in the phosphor containing groove; and
solidifying the phosphor to complete packaging a light emitting diode.

2. The method of packaging a light emitting diode on a through-hole substrate as recited in claim 1, wherein the at least one phosphor containing groove comes with a size and a shape including a horizontal shape, a wavy shape, an arc shape and an irregular shape.

3. The method of packaging a light emitting diode on a through-hole substrate as recited in claim 1, wherein the lens is made of a transparent optical material.

4. The method of packaging a light emitting diode on a through-hole substrate as recited in claim 1, wherein the phosphor comes with a required quantity including a multilayer, an uneven thickness and an unequal thickness.

5. The method of packaging a light emitting diode on a through-hole substrate as recited in claim 1, wherein the phosphor comprises a fluorescent powder and a glue.

6. The method of packaging a light emitting diode on a through-hole substrate as recited in claim 1, wherein the phosphor is solidified by a baking method.
